(19) United States
(12) Patent Application Publication
(10) Pub. No.: US 2018/0335828 A1
(43) Pub. Date: Nov. 22, 2018

(54) SYSTEMS AND METHODS FOR REDUCING MEMORY POWER CONSUMPTION VIA DEVICE-SPECIFIC CUSTOMIZATION OF DDR INTERFACE PARAMETERS

(71) Applicant: QUALCOMM INCORPORATED, SAN DIEGO, CA (US)

(72) Inventors: DEXTER CHUN, SAN DIEGO, CA (US); RICHARD STEWART, SAN DIEGO, CA (US)

(21) Appl. No.: 15/600,318

(22) Filed: May 19, 2017

(51) Int. Cl. G06F 1/32

(52) U.S. Cl. CPC G06F 1/3275; G11C 2207/2227; G06F 1/3287

(57) ABSTRACT

Systems and methods are disclosed for reducing double data rate (DDR) memory power consumption via device-specific customization of DDR interface parameters. One embodiment comprises a method for minimizing double data rate (DDR) power consumption. The method selects one of a plurality of operating points for a DDR interface electrically coupling a DDR memory to a memory controller residing on a system on chip (SoC). The memory controller executes a memory test via the DDR interface at the selected operating point. During the execution of the memory test at the selected operating point, the method determines an optimal value of a setting for one or more DDR interface parameters associated with the DDR interface that minimizes memory power consumption and maintains a predetermined DDR eye margin.

### DESCRIPTION OF THE RELATED ART

Portable computing devices (e.g., cellular telephones, smart phones, tablet computers, portable digital assistants (PDAs), portable game consoles, wearable devices, and other battery-powered devices) and other computing devices continue to offer an ever-expanding array of features and services, and provide users with unprecedented levels of access to information, resources, and communications. To keep pace with these service enhancements, such devices have become more powerful and more complex. Portable computing devices now commonly include a system on chip (SoC) comprising a plurality of memory clients embedded on a single substrate (e.g., one or more central processing units (CPUs), a graphics processing unit (GPU), digital signal processors (DSPs), etc.). The memory clients may read data from and store data in an external dynamic random access memory (DRAM) electrically coupled to the SoC via a high-speed bus, such as, a double data rate (DDR) bus.

Although various memory standards define the protocols and timings with which the SoC may interface with the DRAM, existing system have several disadvantages for selecting optimal bandwidth/frequency operating points. In existing systems, there are generally three degrees of freedom from which the SoC may select the optimal operating points. First, there are silicon various between DRAM suppliers, between different process nodes, and to a large extent between different wafers coming from the same supplier and process node. Second, there are channel variations between platform industrial designs, SoC and DRAM package designs, and radio frequency compliance. Third, various DRAM interface parameter settings (e.g., clock frequency, latency, on-die termination, etc.) may be adjusted.

Existing systems employ best-effort lumped parameters for these variables, which are designed to provide reliable error-free operation. Such a “one-size-to-fit-all” parameter setting can be wasteful of energy because there may be device samples that outperform the norm and could benefit from optimized settings.

Accordingly, there is a need for improved systems and methods for customizing DRAM interface parameter settings to enable individual units to expend the least amount of energy and to allow finer granularity of bandwidth/frequency operating points.

### SUMMARY OF THE DISCLOSURE

Systems and methods are disclosed for reducing double data rate (DDR) memory power consumption via device-specific customization of DDR interface parameters. One embodiment comprises a method for minimizing double data rate (DDR) power consumption. The method selects one of a plurality of operating points for a DDR interface electrically coupling a DDR memory to a memory controller residing on a system on chip (SoC). The memory controller executes a memory test via the DDR interface at the selected operating point. During the execution of the memory test at the selected operating point, the method determines an optimal value of a setting for one or more DDR interface parameters associated with the DDR interface that minimizes memory power consumption and maintains a predetermined DDR eye margin.

Another embodiment of a system comprises a double date rate (DDR) memory and a system on chip (SoC). The SoC comprises a memory controller electrically coupled to the DDR memory via a DDR interface. The memory controller is configured to execute a memory test via the DDR interface at one or more of a plurality of operating points. During the execution of the memory test, the memory controller determines an optimal value of a setting for one or more DDR interface parameters associated with the DDR interface that minimizes memory power consumption and maintains a predetermined DDR eye margin.

### BRIEF DESCRIPTION OF THE DRAWINGS

In the Figures, like reference numerals refer to like parts throughout the various views unless otherwise indicated. For reference numerals with letter character designations such as “102A” or “102B”, the letter character designations may differentiate two like parts or elements present in the same Figure. Letter character designations for reference numerals may be omitted when it is intended that a reference numeral to encompass all parts having the same reference numeral in all Figures.

FIG. 1 is a block diagram of an embodiment of a system for reducing double data rate (DDR) memory power consumption by customizing device-specific DDR interface parameters.

FIG. 2 is a flowchart illustrating an embodiment of a method for reducing DDR memory power consumption by customizing device-specific DDR interface parameters.

FIG. 3 is an exemplary graph illustrating memory power consumption at various voltage frequency bins for two different sample devices incorporating the system of FIG. 1.

FIG. 4 is a flowchart illustrating another embodiment of a method for reducing DDR memory power consumption by customizing device-specific DDR interface parameters during OEM testing.

FIG. 5 is a table illustrating various exemplary common DDR interface parameters that may be customized to minimize memory power consumption while maintaining a predetermined DDR eye margin.

FIG. 6 illustrates an embodiment of the physical layer channel coupling the SoC memory controller PHY to the DRAM PHY.

FIG. 7 illustrates an exemplary DDR data eye with corresponding predetermined DDR eye margins.

FIG. 8 is a block diagram of an exemplary embodiment of a portable computing device for incorporating the system of FIG. 1.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

The term “content” may also include files having executable content, such as: object code, scripts, byte code, markup language files, and patches. In addition, “content” referred to herein, may also include files that are not executable in nature, such as documents that may need to be opened or other data files that need to be accessed.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “communication device,” “wireless device,” “wireless telephone”, “wireless communication device,” and “wireless handset” are used interchangeably. With the advent of third generation (“3G”), fourth generation (“4G”), fifth generation (“5G”) and other wireless technology, greater bandwidth availability has enabled more portable computing devices with a greater variety of wireless capabilities.

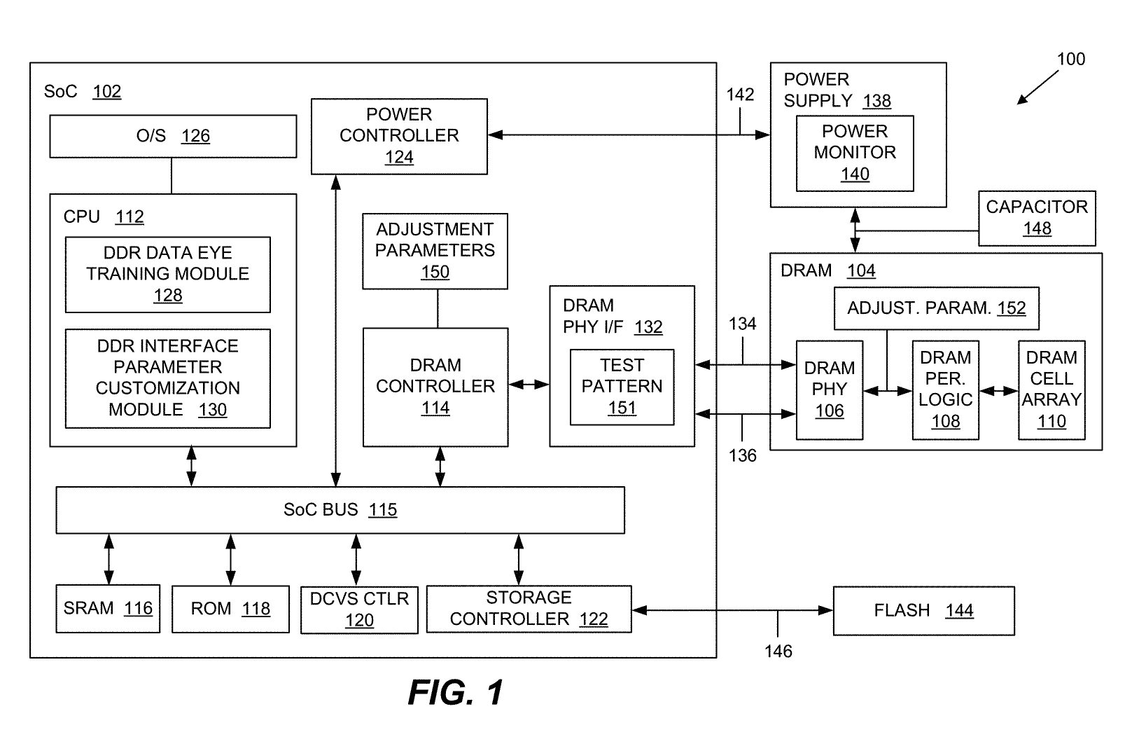

FIG. 1 illustrates an embodiment of a system 100 for reducing memory power consumption by customizing device-specific double data rate (DDR) interface parameters. The system 100 comprises a system on chip (SoC) 102 electrically coupled to a memory via a DDR interface. As known in the art, the DDR interface comprises a physical layer channel or bus that transfers data on both a rising and falling edges of a clock signal. In the embodiment of FIG. 1, the memory comprises a dynamic random access memory (DRAM) 104, and the DDR interface comprises a DRAM clock 136 and a DRAM control and data bus 134. It should be appreciated that system 100 may be implemented in any computing device, including a personal computer, a workstation, a server, a laptop computer, a gaming console, and a portable computing device (PCD), such as a cellular telephone, a smartphone, a portable digital assistant (PDA), a portable game console, a navigation device, a tablet computer, a fitness computer, and a wearable device (e.g., a sports watch, a fitness tracking device, etc.) or other battery-powered devices with a wireless connection or link.

The SoC 102 comprises various on-chip components electrically coupled via SoC bus 115. In the embodiment of FIG. 1, the SoC 102 comprises one or more memory clients (e.g., central processing unit(s) (CPU) 112, graphics processing unit(s) (GPU), digital signal processor(s) (DSPs)), a static random access memory (SRAM) 116, read only memory (ROM) 118, a DRAM controller 114, a storage controller 122, a power controller 124, and a dynamic clock and voltage scaling (DCVS) controller 120 interconnected via SoC bus 115.

The CPU 112 may support a high-level operating system (O/S) 126. As described below in more detail, the CPU 112 may execute various modules (e.g., DDR data eye training module 128, DDR interface parameter customization module 130) for performing the customization of device-specific DDR interface parameters.

The power controller 124 is electrically coupled to a power supply 138 via a power control bus 142, which comprises a power monitor 140 configured to measure energy usage associated with the SoC 102 and the DRAM 104 and, thereby, monitor memory power consumption.

As further illustrated in FIG. 1, the storage controller 122 may be electrically coupled via a storage bus 146 to external storage memory, such as, for example, flash memory 144 or other non-volatile memory device(s). Storage controller 122 controls communication with the external storage memory.

The DCVS controller 120 is configured to implement various DCVS techniques. As known in the art, the DCVS techniques involve selectively adjusting the frequency and/or voltage applied to the SoC components (e.g., CPU 112, power controller 124, and other hardware devices) to yield a desired performance and/or power efficiency characteristics.

The DRAM controller 114 comprises a physical layer 132, which is electrically coupled to a physical layer 106 residing on DRAM 104. Physical layer 106 is coupled to DRAM peripheral logic 108, which is coupled to a cell array 110.

As further illustrated in FIG. 1, the system 100 comprises specially-configured modules (i.e., DDR interface parameter customization module 130) for implementing device-specific customization of DDR interface parameters. It should be appreciated that finer granularity control of bandwidth/frequency operating points via device-specific customized DDR interface parameters may enable individual units of the same system design to consume less power at any given bandwidth/frequency operating point.

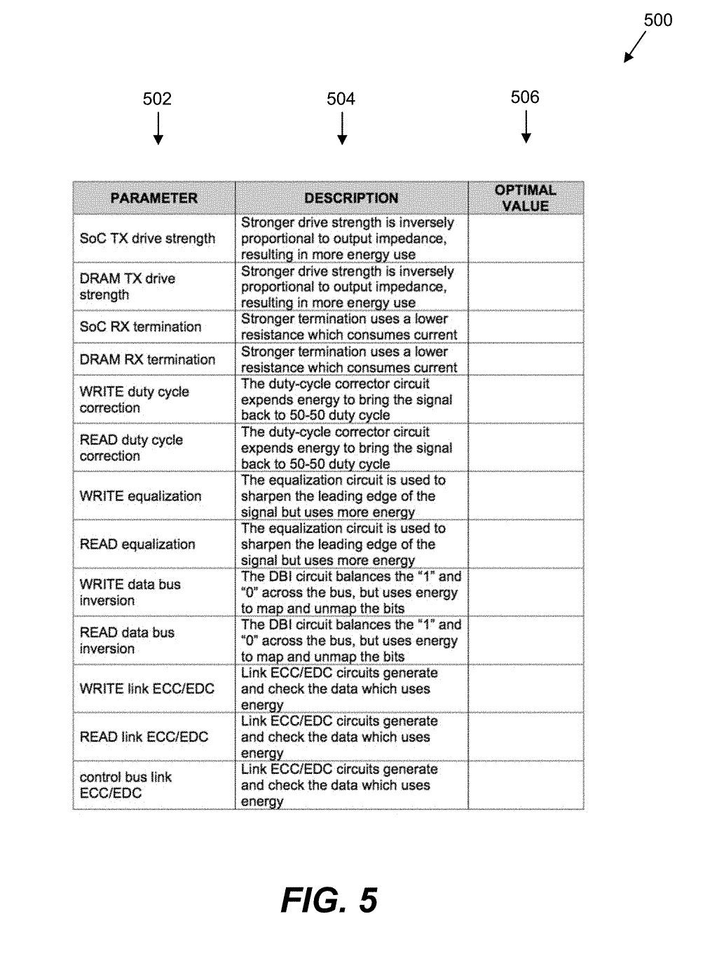

As known in the art, the memory interface frequency may be determined by the required traffic bandwidth requested from all memory clients. This frequency may rise or fall as the traffic bandwidth demand changes. Typically, several voltage/frequency bins may be used. For each frequency operating point, the system comprising the SoC, the physical channel, and the DRAM are tuned during factory initialization to establish “common parameter settings” that will provide reliable operation. FIG. 5 illustrates an exemplary embodiment of common parameter settings that may be used to improve the electrical signal quality of the DRAM control and data bus 134. The common parameter settings resulting from the tuning are tested across a large sample size of identical system design units (differing only by the individual SoC and DRAM component serial numbers), and then a common parameter setting is deployed, which represents a compromise to support a least common denominator across part-to-part variation. The common parameter settings are reliable and easy to deploy, but due to chip-to-chip and system variability, the settings may be conservative for a large majority of systems and result in unnecessary power consumption and/or reduced performance.

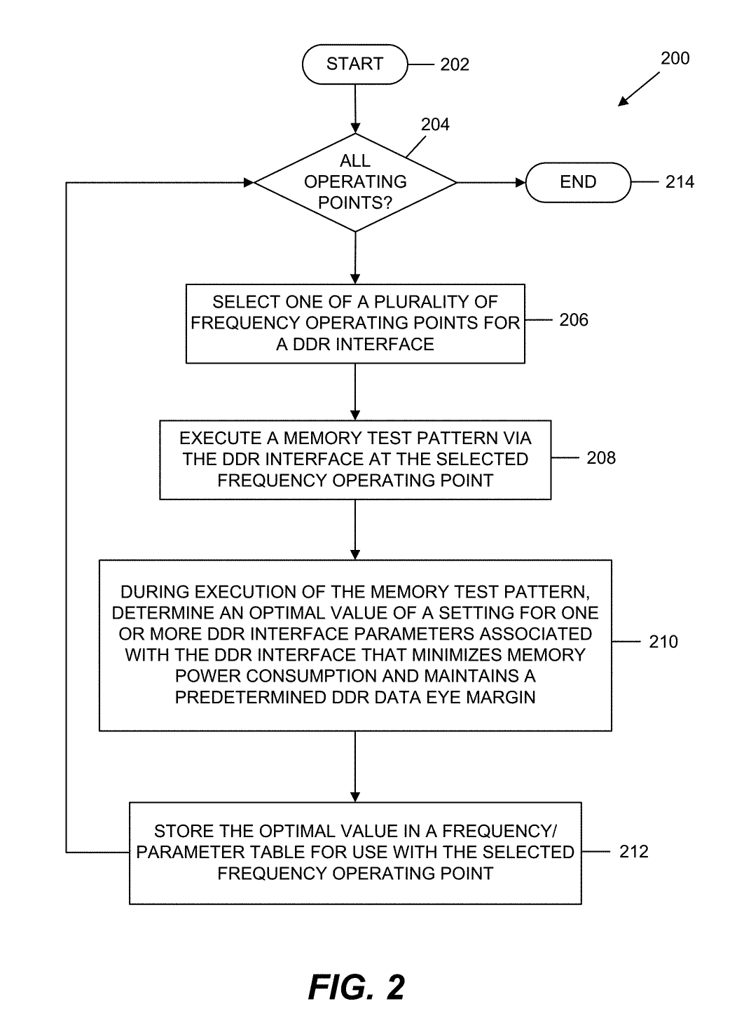

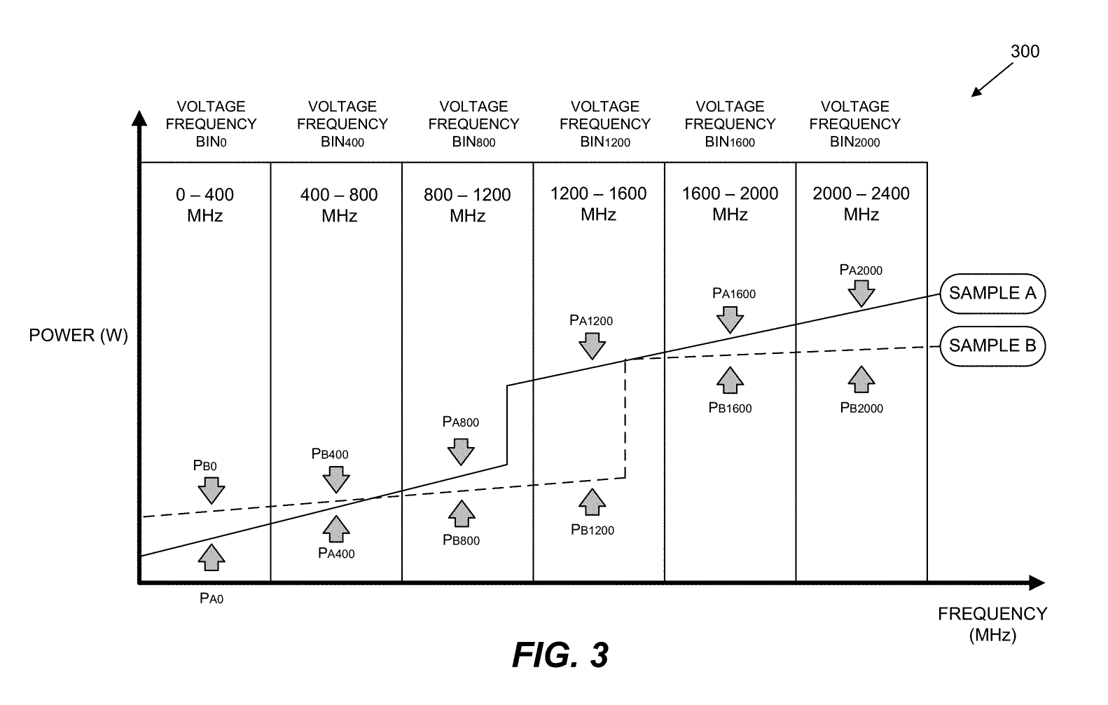

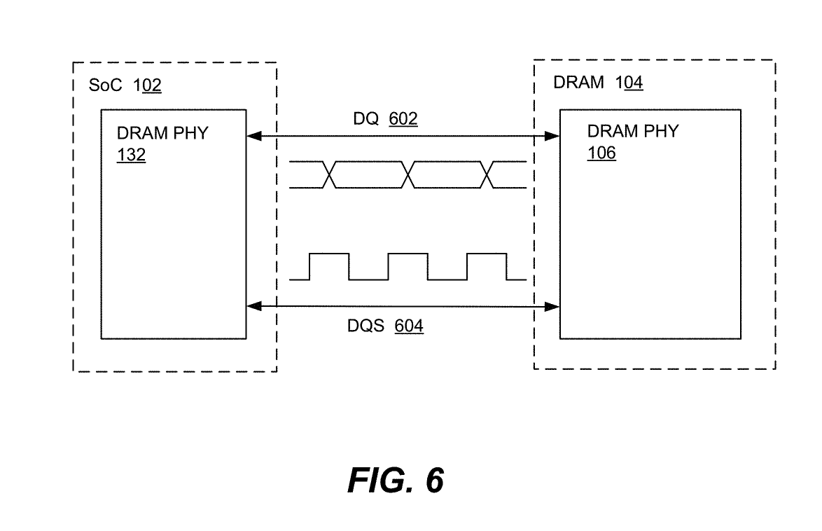

FIG. 2 illustrates an embodiment of a method 200 implemented in the system 100 for reducing DDR memory power consumption by customizing device-specific DDR interface parameters. The method 200 may be initiated, at block 202, as part of a factory initialization/configuration process or upon device boot-up. It should be appreciated that the method 200 may be performed successively at device boot-up to compensate for aging over the lifetime of the device. The method 200 may be initiated and controlled by DDR interface parameter customization module 130. As illustrated by decision block 204, the method 200 may be repeated for each of a plurality of bandwidth/frequency operating points. At block 206, one of the bandwidth/frequency operating points is selected. At block 208, a memory test pattern 151 is initiated at the selected operating point. During execution of the memory test 151 at the selected operating point, at block 210, the method 200 determines an optimal value of a setting for one or more DDR interface parameters associated with the DDR interface (i.e., buses 134 and 136) that (1) minimizes memory power consumption and (2) maintains predetermined DDR data eye margin(s). The feature of minimizing memory power consumption is described below with reference to FIG. 3. The feature of maintaining predetermined DDR date eye margin(s) may be facilitated by communication with DDR data eye training module 120, which is described below with reference to FIGS. 6 & 7. At block 212, the optimal value of the DDR interface parameter setting is stored in a memory for operational use at the selected operating point. For example, in an embodiment, the optimal value of the DDR interface parameter setting may be stored in a non-volatile memory and, in response to a subsequent boot of the computing device, the optimal value of the setting may be retrieved from the non-volatile memory.

In this manner, the DDR interface parameter settings at each frequency operating point may be optimized for individual devices or units to address potential chip-to-chip variation. During the execution of the memory test pattern 151 at the various frequency operating points, the power monitor 140 may measure power consumption of the SoC 102 and DRAM 104 while the DDR interface parameter settings are adjusted. It should be appreciated that the memory test pattern 151 exercises the DRAM 104 to characterize the magnitude of the power consumption for each frequency bin. There may be multiple reliable or successful parameter settings for each frequency bin. In an embodiment, the optimal setting is determined to be the setting that results in the lowest power consumption while maintaining the DDR data eye margin within predetermined margin(s).

FIG. 3 illustrates an exemplary power vs. bandwidth graph 300 for two different samples (i.e., sample A and sample B) having the identical system design 100. For example, sample A may comprise a first portable computing device having a system design 100, and sample B may comprise a second portable computing device having the same system design 100. In this example, the system 100 provides six voltage frequency bins. A first voltage frequency bin₀ comprises the frequency range 0-400 MHz. A second voltage frequency bin₄₀₀ comprises the frequency range 400-800 MHz. A third voltage frequency bing₈₀₀ comprises the frequency range 800-1200 MHz. A fourth voltage frequency bin₁₂₀₀ comprises the frequency range 1200-1600 MHz. A fifth voltage frequency bin₁₆₀₀ comprises the frequency range 1600-2000 MHz. A sixth voltage frequency bin₂₀₀₀ comprises the frequency range 2000-2400 MHz. The solid line plots the memory power consumption measured by the power monitor 140 for a first device (sample A). The dashed line plots the memory power consumption measured by the power monitor 140 for a second device (sample B).

One of ordinary skill in the art will appreciate that the variations in memory power consumption between sample A and sample B may result from chip-to-chip variations related to the SoC 102 chip, the DRAM 104 chip(s), and/or variations in the physical channel comprising DRAM control and data bus 134 and DRAM clock bus 136. These and other variations between different devices having an identical system design may be caused by silicon process variation(s) between chips, which affect the DDR interface parameter settings that determine the operational characteristics such as interface power, frequency of operation, and bit error rate. For example, if either the SoC 102 or any DRAM 104 silicon is “slow”, then for a given target frequency of operation the device may need to be configured with parameters, such as, drive strength or termination strength to compensate, resulting in higher power consumption compared to “fast” silicon. “Fast” or “slow” refers to the circuit signal propagation delay, rise/fall times, and skew characteristics.

The exemplary graph 300 shows that the power monitor 140 may determine different power consumption levels at the same frequency bins for sample A and sample B. For example, sample A has the lowest energy at low frequency (i.e., P_{A0} in bin₀). Sample B has the lowest energy at peak frequency (i.e. P_{B2000} in bin₂₀₀₀). Sample A has a generally steeper slope than sample B (i.e., [P_{A800}−P_{A0}]>[P_{B800}−P_{B0}]). Sample A may require elevated power earlier at 1100 MHz compared to sample B at 1500 MHz. To minimize memory power consumption, the power monitor 140 residing in sample A and sample B may measure the corresponding illustrated memory power consumption and determine the DDR interface parameter settings, for each frequency bin, that results in the lowest memory power consumption for each sample.

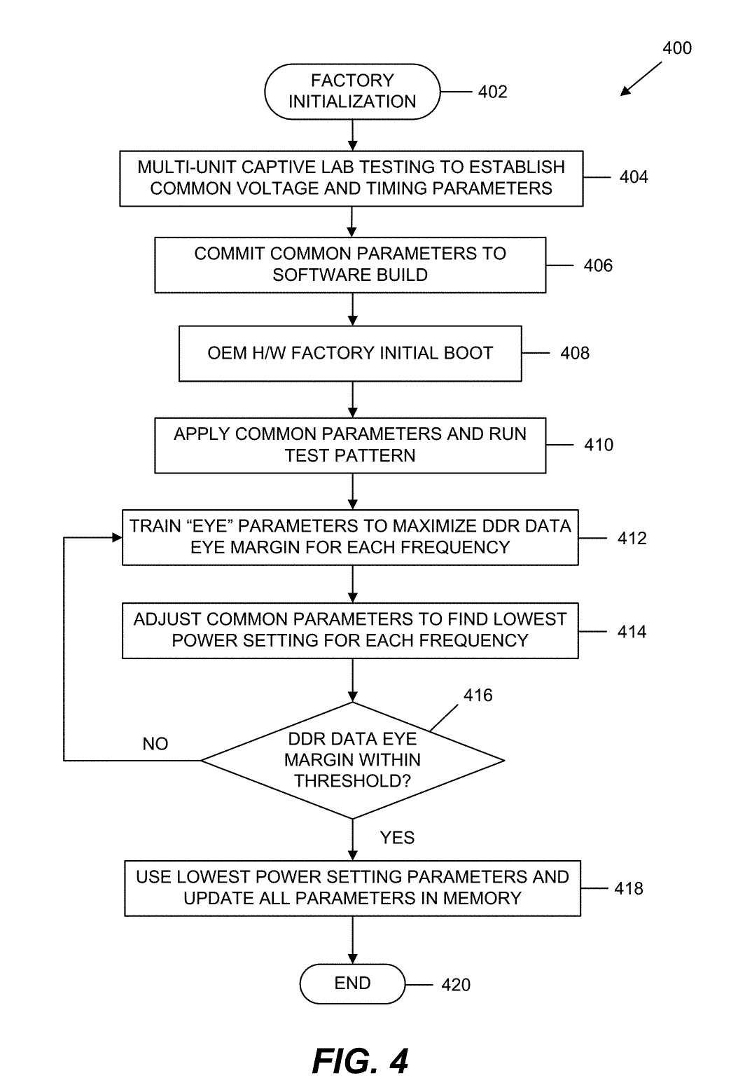

FIG. 4 is a flowchart illustrating another embodiment of a method 400 for reducing DDR memory power consumption by customizing device-specific DDR interface parameters. A factory initialization may begin at block 402. At block 404, captive lab testing is performed for a plurality of units or devices comprising the system 100. The captive lab testing involves determining common voltage and timing parameters. In an embodiment, the multi-unit captive lab testing may involve a determination of common parameter settings or values, in the conventional manner described above. The common parameter settings or values may involve, for example, any of the parameters illustrated in column 502 in the data table 500 of FIG. 5: SoC TX drive strength; DRAM TX drive strength; SoC RX termination; DRAM RX termination; WRITE duty cycle correction; READ duty cycle correction; WRITE equalization; READ equalization; WRITE data bus inversion; READ data bus inversion; WRITE link ECC/EDC; READ link ECC/EDC; and control bus link ECC/EDC. Column 504 describes how adjustments in the corresponding value or setting impacts memory power consumption. It should be appreciated that the multi-unit captive lab testing may determine so-called common parameter settings or values that result in reliable, error-free operation of the system 100.

At block 406, the common parameter settings or values may be committed to a software build for devices incorporating the system 100. At block 408, a device incorporating the system 100 may be initially booted up during OEM factory installation. At block 410, the common parameter settings or values are applied to the device and the system 100 may begin executing the memory test pattern 151. At block 412, the DDR date eye training module 128 may begin training DDR data eye parameters (e.g., horizontal eye sampling point, vertical eye sampling point) to maximize DDR data eye margins for each frequency operating point. It should be appreciated that these DDR data eye parameters may not affect the shape, size, and/or quality of the data eye. For example, the DDR data eye training may determine an optimal sampling decision point within the eye. In contrast, the common parameter settings are capable of changing the shape, size, and/or quality of the data eye (e.g., making the eye clean versus noisy, large versus closed, etc.).

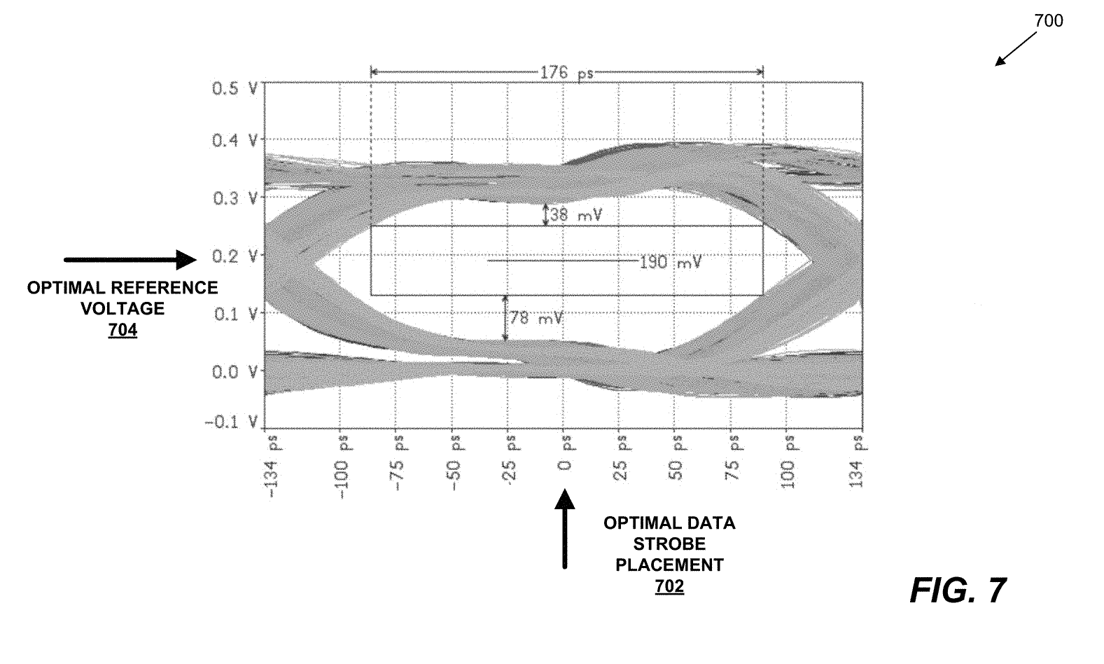

Referring to FIG. 6, the SoC 102 and the DRAM 104 transmit and receive data using a data strobe signal (DQS) 604 and a data signal (DQ) 602. The DQS signal 604 comprises a reference signal that transitions between logical 0 and 1. The DQ data 602 is captured on the transitioning edge of the DQS signal 604 on both the rising and falling edges. As known in the art, a DDR data eye 700 (FIG. 7) is generated when multiple captured data signals are superimposed on one another. The rising time refers to the time to transition from logical 0 to 1, and the falling time refers to the time to transition from logical 1 to 0. The reference voltage refers to the threshold voltage for differentiating logical 1 and 0.

FIG. 7 illustrates an exemplary DDR data eye 700. Time is represented on the x-axis, and the reference voltage is represented on the y-axis. The DDR data eye 700 comprises a plurality of captured DQ signals superimposed on one another. The DDR data eye training module 128 may be configured to determine a center of the DDR data eye 700, which corresponds to an optimal data strobe placement 702 and an optimal reference voltage 704. The DDR data eye training module 128 may implement various algorithms for efficiently determining the best data strobe placement and reference voltage value pair for each of the frequency operating points.

Referring again to FIG. 4, when the “eye” parameters have been determined to maximize DDR data eye margins for each frequency operating point, the method 400 may initiate a process to determine customized, device-specific common parameters. At block 414, the settings or values for the common parameters (FIG. 5) may be adjusted while the power monitor 140 measures power consumption. In an embodiment, the DDR interface parameter customization module 130 (FIG. 1) sweeps through the values for one or more of the parameters identified in the table of FIG. 5 to determine the setting that yields the lowest power consumption for each frequency. At decision block 416, if the lowest power setting does not maintain the DDR data eye 700 within predetermined eye margin(s), the process may return to block 412. For example, referring to FIG. 7, the predetermined eye margin(s) may comprise a minimum value in the time domain (e.g., 176 ps) and/or minimum upper and lower voltage margins (e.g., 38 mV for the upper margin and 78 mV for the lower margin). If, however, the lowest power setting does maintain the DDR data eye 700 within the predetermined eye margin(s), the table 500 may be updated with the optimal setting or value (block 418). After determining adjusted settings or values for the common interface parameters for each frequency, the factory initialization may terminate at block 420. In this manner, the end result is a reliable bus operation that meets the predetermined eye margin(s) with common parameter settings that use the least energy.

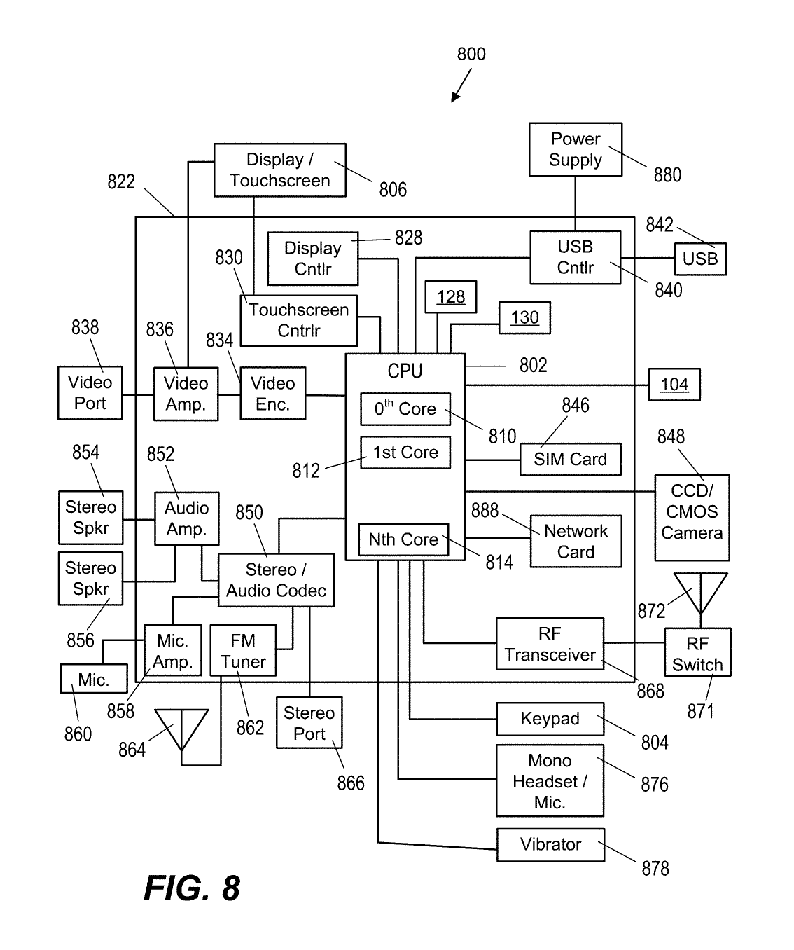

As mentioned above, the system 100 may be incorporated into any desirable computing system. FIG. 8 illustrates the system 100 incorporated in an exemplary portable computing device (PCD) 800. It will be readily appreciated that certain components of the system 100 may be included on the SoC 822 (e.g., DRAM controller 114, DRAM PHY 132, test pattern 151, DDR data eye training module 128, DDR interface parameter customization module 130, etc.) while other components (e.g., DRAM 104) may be external components coupled to the SoC 822. The SoC 822 may include a multicore CPU 802. The multicore CPU 802 may include a zeroth core 810, a first core 812, and an Nth core 814. One of the cores may comprise, for example, a graphics processing unit (GPU) with one or more of the others comprising the CPU 802.

A display controller 828 and a touch screen controller 830 may be coupled to the CPU 802. In turn, the touch screen display 806 external to the on-chip system 822 may be coupled to the display controller 828 and the touch screen controller 830.

FIG. 8 further shows that a video encoder 834, e.g., a phase alternating line (PAL) encoder, a sequential color a memoire (SECAM) encoder, or a national television system(s) committee (NTSC) encoder, is coupled to the multicore CPU 802. Further, a video amplifier 836 is coupled to the video encoder 834 and the touch screen display 806. Also, a video port 838 is coupled to the video amplifier 836. As shown in FIG. 8, a universal serial bus (USB) controller 840 is coupled to the multicore CPU 802. Also, a USB port 842 is coupled to the USB controller 840.

Further, as shown in FIG. 8, a digital camera 848 may be coupled to the multicore CPU 802. In an exemplary aspect, the digital camera 848 is a charge-coupled device (CCD) camera or a complementary metal-oxide semiconductor (CMOS) camera.

As further illustrated in FIG. 8, a stereo audio coder-decoder (CODEC) 850 may be coupled to the multicore CPU 802. Moreover, an audio amplifier 852 may coupled to the stereo audio CODEC 850. In an exemplary aspect, a first stereo speaker 854 and a second stereo speaker 856 are coupled to the audio amplifier 852. FIG. 8 shows that a microphone amplifier 858 may be also coupled to the stereo audio CODEC 850. Additionally, a microphone 860 may be coupled to the microphone amplifier 858. In a particular aspect, a frequency modulation (FM) radio tuner 862 may be coupled to the stereo audio CODEC 850. Also, an FM antenna 864 is coupled to the FM radio tuner 862. Further, stereo headphones 866 may be coupled to the stereo audio CODEC 850.

FIG. 8 further illustrates that a radio frequency (RF) transceiver 868 may be coupled to the multicore CPU 802. An RF switch 870 may be coupled to the RF transceiver 868 and an RF antenna 872. A keypad 804 may be coupled to the multicore CPU 802. Also, a mono headset with a microphone 876 may be coupled to the multicore CPU 802. Further, a vibrator device 878 may be coupled to the multicore CPU 802.

FIG. 8 also shows that a power supply 880 may be coupled to the on-chip system 822. In a particular aspect, the power supply 880 is a direct current (DC) power supply that provides power to the various components of the PCD 800 that require power. Further, in a particular aspect, the power supply is a rechargeable DC battery or a DC power supply that is derived from an alternating current (AC) to DC transformer that is connected to an AC power source.

FIG. 8 further indicates that the PCD 800 may also include a network card 888 that may be used to access a data network, e.g., a local area network, a personal area network, or any other network. The network card 888 may be a Bluetooth network card, a WiFi network card, a personal area network (PAN) card, a personal area network ultra-low-power technology (PeANUT) network card, a television/cable/satellite tuner, or any other network card well known in the art. Further, the network card 888 may be incorporated into a chip, i.e., the network card 888 may be a full solution in a chip, and may not be a separate network card 888.

As depicted in FIG. 8, the touch screen display 806, the video port 838, the USB port 842, the camera 848, the first stereo speaker 854, the second stereo speaker 856, the microphone 860, the FM antenna 864, the stereo headphones 866, the RF switch 870, the RF antenna 872, the keypad 874, the mono headset 876, the vibrator 878, and the power supply 880 may be external to the on-chip system 822.

It should be appreciated that one or more of the method steps described herein may be stored in the memory as computer program instructions, such as the modules described above. These instructions may be executed by any suitable processor in combination or in concert with the corresponding module to perform the methods described herein.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example.

Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the Figures which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, NAND flash, NOR flash, M-RAM, P-RAM, R-RAM, CD-ROM or other optical disk storage, magnetic disk storage or other magnetic storage devices, or any other medium that may be used to carry or store desired program code in the form of instructions or data structures and that may be accessed by a computer.

Also, any connection is properly termed a computer-readable medium. For example, if the software is transmitted from a website, server, or other remote source using a coaxial cable, fiber optic cable, twisted pair, digital subscriber line (“DSL”), or wireless technologies such as infrared, radio, and microwave, then the coaxial cable, fiber optic cable, twisted pair, DSL, or wireless technologies such as infrared, radio, and microwave are included in the definition of medium.

Disk and disc, as used herein, includes compact disc (“CD”), laser disc, optical disc, digital versatile disc (“DVD”), floppy disk and blu-ray disc where disks usually reproduce data magnetically, while discs reproduce data optically with lasers. Combinations of the above should also be included within the scope of computer-readable media.

Alternative embodiments will become apparent to one of ordinary skill in the art to which the invention pertains without departing from its spirit and scope. Therefore, although selected aspects have been illustrated and described in detail, it will be understood that various substitutions and alterations may be made therein without departing from the spirit and scope of the present invention, as defined by the following claims.

What is claimed is:

1. A method for minimizing double data rate (DDR) power consumption, the method comprising:
selecting one of a plurality of operating points for a DDR interface electrically coupling a DDR memory to a memory controller residing on a system on chip (SoC);
the memory controller executing a memory test via the DDR interface at the selected operating point; and
during the execution of the memory test at the selected operating point, determining a value of a setting for one or more DDR interface parameters associated with the DDR interface that minimizes memory power consumption and maintains a predetermined DDR eye margin.

2. The method of claim 1, wherein the plurality of operating points comprises a plurality of voltage/frequency levels for the DDR interface.

3. The method of claim 1, wherein the determining the value of the setting for the one or more DDR interface parameters during the execution of the test pattern at the selected operating point comprises:
adjusting the setting for the one or more or more DDR interface parameters;
measuring memory power consumption at the adjusted settings; and
measuring the DDR eye margin.

4. The method of claim 1, wherein the one or more DDR interface parameters comprises one or more of a transmitter drive strength, a receiver termination value, a duty cycle correction on/off value, an equalization on/off value, a data bus inversion on/off value, and a link error correcting code (ECC) on/off value.

5. The method of claim 1, further comprising:
storing the value of the setting for one or more DDR interface parameters in a non-volatile memory.

6. The method of claim 1, wherein the memory test is executed during a factory installation of a computing device comprising the SoC and the DDR memory.

7. The method of claim 1, wherein the computing device comprises one of a smart phone, a table computer, and a wearable computing device.

8. The method of claim 1, wherein the memory test is executed during a boot-up of the SoC.

9. A system for minimizing double data rate (DDR) power consumption, the system comprising:
means for selecting one of a plurality of operating points for a DDR interface electrically coupling a DDR memory to a memory controller residing on a system on chip (SoC);
means for executing a memory test via the DDR interface at the selected operating point; and
means for determining, during the execution of the memory test at the selected operating point, a value of a setting for one or more DDR interface parameters associated with the DDR interface that minimizes memory power consumption and maintains a predetermined DDR eye margin.

10. The system of claim 9, wherein the plurality of operating points comprises a plurality of voltage/frequency levels for the DDR interface.

11. The system of claim 9, wherein the means for determining the value of the setting for the one or more DDR interface parameters during the execution of the test pattern at the selected operating point comprises:
means for adjusting the setting for the one or more or more DDR interface parameters;
means for measuring memory power consumption at the adjusted settings; and
means for measuring the DDR eye margin.

12. The system of claim 9, wherein the one or more DDR interface parameters comprises one or more of a transmitter drive strength, a receiver termination value, a duty cycle correction on/off value, an equalization on/off value, a data bus inversion on/off value, and a link error correcting code (ECC) on/off value.

13. The system of claim 9, wherein the memory test is executed during a factory installation of a computing device comprising the SoC and the DDR memory.

14. The system of claim 9, wherein the computing device comprises one of a smart phone, a table computer, and a wearable computing device.

15. The system of claim 9, wherein the memory test is executed in response to a boot-up of the SoC.

16. A computer program embodied in a non-transitory computer readable medium and executed by a processor for minimizing double data rate (DDR) power consumption, the computer program comprising logic configured to:
select one of a plurality of operating points for a DDR interface electrically coupling a DDR memory to a memory controller residing on a system on chip (SoC);
initiate execution of a memory test via the DDR interface at the selected operating point; and
determine, during the execution of the memory test at the selected operating point, an value of a setting for one or more DDR interface parameters associated with the DDR interface that minimizes memory power consumption and maintains a predetermined DDR eye margin.

17. The computer program of claim 16, wherein the plurality of operating points comprises a plurality of voltage/frequency levels for the DDR interface.

18. The computer program of claim 16, wherein the logic configured to determine the value of the setting for the one or more DDR interface parameters during the execution of the test pattern at the selected operating point comprises logic configured to:
adjust the setting for the one or more or more DDR interface parameters;
measure memory power consumption at the adjusted settings; and
measure the DDR eye margin.

19. The computer program of claim 16, wherein the one or more DDR interface parameters comprises one or more of a transmitter drive strength, a receiver termination value, a duty cycle correction on/off value, an equalization on/off value, a data bus inversion on/off value, and a link error correcting code (ECC) on/off value.

20. The computer program of claim 16, wherein the memory test is executed during a factory installation of a computing device comprising the SoC and the DDR memory, and the computer program further comprises logic configured to:
store the value of the setting for the one or more DDR interface parameters in a non-volatile memory; and
in response to a subsequent boot of the computing device, retrieve the value of the setting for the one or more DDR interface parameters from the non-volatile memory.

21. The computer program of claim 16, wherein the computing device comprises one of a smart phone, a table computer, and a wearable computing device.

22. The computer program of claim 16, wherein the memory test is executed during a boot-up of the SoC.

23. A system for minimizing double data rate (DDR) power consumption, the system comprising:
a double date rate (DDR) memory; and
a system on chip (SoC) comprising a memory controller electrically coupled to the DDR memory via a DDR interface, the memory controller configured to execute a memory test via the DDR interface at one or more of a plurality of operating points and, during the execution of the memory test, determine an value of a setting for one or more DDR interface parameters associated with the DDR interface that minimizes memory power consumption and maintains a predetermined DDR eye margin.

24. The system of claim 23, further comprising:
a power source electrically coupled to the SoC and the DDR memory, the power source comprising a power monitor component for measuring the memory power consumption during the memory test.

25. The system of claim 23, wherein the plurality of operating points comprises a plurality of voltage/frequency levels for the DDR interface.

26. The system of claim 23, wherein the memory controller determines the value of the setting for the one or more DDR interface parameters during the execution of the test pattern at the selected operating point by:
adjusting the setting for the one or more or more DDR interface parameters;
measuring memory power consumption at the adjusted settings; and
measuring the DDR eye margin.

27. The system of claim 23, wherein the one or more DDR interface parameters comprises one or more of a transmitter drive strength, a receiver termination value, a duty cycle correction on/off value, an equalization on/off value, a data bus inversion on/off value, and a link error correcting code (ECC) on/off value.

28. The system of claim 23, wherein the memory test is executed during a factory installation of a computing device comprising the SoC and the DDR memory.

29. The system of claim 23, wherein the computing device comprises one of a smart phone, a table computer, and a wearable computing device.

30. The system of claim 23, wherein the memory test is executed during a boot-up of the SoC.
